(19) United States
(12) Patent Application Publication
(10) Pub. No.: US 2019/0021169 A1
(43) Pub. Date: Jan. 17, 2019

(54) METHOD FOR PRODUCING SUPPORT STRUCTURES FOR LIGHTING DEVICES AND CORRESPONDING DEVICE

(71) Applicant: OSRAM GmbH, Munich (DE)

(72) Inventors: Lorenzo Baldo, Giavera del Montello (IT); Alessio Griffoni, Fosso (IT); Thomas Rieger, Aufhausen (DE)

(21) Appl. No.: 16/032,089

(22) Filed: Jul. 11, 2018

(30) Foreign Application Priority Data
Jul. 11, 2017 (IT) 102017000078083

(51) Int. Cl. H05K 1/18; H05K 3/12; H05K 3/40; F21V 19/00; H05K 3/30; H05K 3/00

(52) U.S. Cl. CPC H05K 1/189; H05K 3/1216; H05K 3/40; H05K 3/125; H05K 3/1283; F21Y 2115/10; F21V 19/0025; H05K 3/303; H05K 3/0052; H05K 2203/013; H05K 2203/0143; H05K 1/181

(57) ABSTRACT

A method for forming support structures for electrically-powered lighting devices, the method comprising: providing an electrically insulating ribbon-like substrate, forming electrically-conductive lines on a surface of the substrate by screen printing of electrically-conductive ink, the screen printing comprising printing a plurality of repeated printed images, which follow one another along a longitudinal direction and are separated from each other by separation gaps, and forming electrically-conductive ink jumpers that extend through the separation gaps and which provide electrical continuity between electrically-conductive lines of adjacent printed images, wherein forming ink jumpers comprises delivering electrically-conductive ink by inkjet printing.

### CROSS-REFERENCE TO RELATED APPLICATION

This application claims priority to Italian Patent Application Serial No.: 102017000078083, which was filed Jul. 11, 2017, and is incorporated herein by reference in its entirety and for all reasons.

### TECHNICAL FIELD

The description refers to lighting devices.

One or more embodiments may refer to lighting devices using electrically-powered light radiation sources, for example solid-state light radiation sources such as LED sources.

### BACKGROUND

In the lighting sector, there is a growing demand for lighting modules, e.g. LEDs, with characteristics of adaptability to the requirements of application and use (so-called “customization”) with reduced development and implementation times.

Satisfying requirements of this nature is particularly demanding in relation to elongated and flexible LED modules (e.g. ribbon-like) that may be produced in the form of structures of a certain length with a particularly high number of electrical units arranged along the module (for example, connected in parallel with each other) and comprising one or more LED chains and the relative driving circuits.

To facilitate the achievement of electrical continuity and uniform functionality over the entire length of the module, it is possible to apply e.g. two or more buses of a certain length.

To facilitate the use of these modules, it is desirable that the user is able to cut the module lengthwise in any position between two adjacent electrical units, so as to be able to have a solution that is adaptable to the requirements of application and use.

From the implementation point of view, it is also desirable that these modules may be produced with reel-to-reel (R2R) methods so as to have modules of a certain length with continuity characteristics with contained costs.

To satisfy this need, it is possible to use flexible structures that are laminated (“clad”) on one side or on two sides with conductive materials such as copper or aluminum and to etch the conductive layers according to the required configuration (layout) of electric lines.

In the case of a change in the layout, this solution requires an almost complete review of the entire printed circuit board, e.g. Flexible Printed Circuit Board—FPCB, with an intervention designed to involve the board manufacturer as well. All this translates into an additional activity with the added costs and time associated with it.

Another solution may envisage the use of electrically-conductive inks printed on a substrate with techniques such as rotogravure, flexographic printing or offset printing.

These printing techniques make it possible to produce continuous, electrically-conductive lines with a certain length. However, these are rather thin lines (for example, with a thickness of less than 10 microns (1 micron=10⁻⁶ m), which results in an increase in electrical resistance, and consequently, in a reduction of the electrical functionality in the case of modules of a certain length.

Also in this case, the electrical layout cannot be customized easily and quickly, as the adaptation to a new layout may involve particularly relevant changes to the processing tools (forms of printing).

Another solution is to use conductive inks printed with rotary printing. This printing technique makes it possible to produce continuous, electrically-conductive lines with a certain length. Also in this case, the electrical configuration or layout cannot, however, be customized quickly, as the adaptation to a new layout may involve relevant changes to the processing tools.

In addition, it should also be taken into account that the electrically-conductive ink formulations that may be used for the printing techniques described above are not many, which constitutes an additional obstacle for the use of these techniques.

Another solution is the printing of electric lines by inkjet printing with conductive inks. This printing technique makes it possible to produce continuous, electrically-conductive lines with a certain length. The layout of electric lines may be easily customized in a short time. However, this printing method is currently limited to the application of thin layers, i.e. a few microns, which results in high production times in cases where it is necessary to produce thick conductive lines.

In the context of use considered here, screen printing with conductive inks proves to be more advantageous with respect to the other printing techniques considered previously. For example, the screen printing may allow the implementation of a new configuration or layout of electrically-conductive lines in a short period of time, and the production and/or procurement of the printing screens may take place rapidly. All this carries the possibility of creating electrically-conductive lines or tracks with a thickness of, for example, between 5 and 50 microns (1 micron=10⁻⁶ m), capable of conducting high currents with reduced electrical resistance. In addition to this, the range of inks that may be used for screen printing is fairly wide.

However, the use of a screen printing technique in reel-to-reel methods may be difficult since it is necessary to maintain a certain separation distance (offset distance) in the order of a few millimeters between two successive printing images, to take into account manufacturing tolerances and possible smearing of the ink. The offset distance therefore does not allow continuous electric lines (buses) to be made that extend along the entire length of the module.

### SUMMARY

One or more embodiments aim to overcome the drawbacks outlined above.

According to one or more embodiments, this object may be achieved by a method having the characteristics referred to in the following description.

One or more embodiments may also concern a corresponding device.

The claims form an integral part of the technical disclosure provided here in relation to the embodiments.

One or more embodiments allow the production of support structures for lighting devices (for example, in the form of Flexible Printed Circuit Boards or FPCB) using e.g. thick film polymeric inks (Polymer Thick Film—PTF) in which electrically-conductive (nano)particles are dispersed, e.g. based on silver or copper. These inks may be printed with screen printing techniques on flexible films, for example, based on polyimide—PI, polyethylene naphthalate, PEN, polyethyleneimine—PEI, ultra-thin glass, etc.).

In one or more embodiments, an electrical continuity of the electrically-conductive lines (for example, at the bus level) between successive printing areas may be achieved by using electrically-conductive ink jumpers formed by inkjet printing, which extend through separation gaps between adjacent printing images.

One or more embodiments may offer one or more of the following advantages:
the possibility of managing the production of new products quickly and with contained costs in a customization perspective, e.g. in relation to flexible and linear LED modules, without causing significant drawbacks, for example, in terms of electrical resistance of the interconnections between successive printing images, since the electrically-conductive ink jumpers may have a thickness equal to or even greater than that of the electric lines formed with screen printing,
the possibility of introducing changes into the basic structure (for example, FPCB and relative layout of the electrically-conductive lines/tracks) at the level of the assembler of the electronic circuits without necessarily involving the supplier of the basic structure,
the possibility of managing different electrical configurations or layouts on a single basic structure (for example, FPCB), and therefore different electric circuits,
the possibility of producing flexible and linear LED modules in the context of a reel-to-reel process,
the possibility of using a screen printing process for the purposes indicated above, and
the possibility of achieving a high level of flexibility in the implementation of the LED module.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various aspects are described with reference to the following drawings, in which:

FIG. 1 exemplifies a screen printing step,

FIG. 2 is a schematic cross-section along the line II-II of FIG. 1,

FIG. 3 exemplifies the formation of ink jumpers,

FIG. 4 is an schematic cross-section along the line IV-IV of FIG. 3, and

FIG. 5 exemplifies the application of light radiation sources.

### DETAILED DESCRIPTION

In the following description various specific details are illustrated aimed at a thorough understanding of examples of embodiments of the present description. One or more embodiments may be implemented without one or more of the specific details, or with other methods, components, materials, etc. In other cases, known structures, materials or operations are not shown or described in detail to avoid obscuring various aspects of the embodiments. The reference to “an embodiment” in the context of this description indicates that a particular configuration, structure or characteristic described in relation to the embodiment is included in at least one embodiment. Therefore, phrases such as “in an embodiment”, possibly present in different places of this description do not necessarily refer to the same embodiment. Moreover, particular configurations, structures or characteristics may be combined in any convenient way in one or more embodiments.

The word “exemplary” or “exemplifies” is used herein to mean “serving as an example, instance, or illustration”. Any embodiment or design described herein as “exemplary” is not necessarily to be construed as preferred or advantageous over other embodiments or designs.

The references used here are only for convenience and do not therefore define the field of protection or the scope of the embodiments.

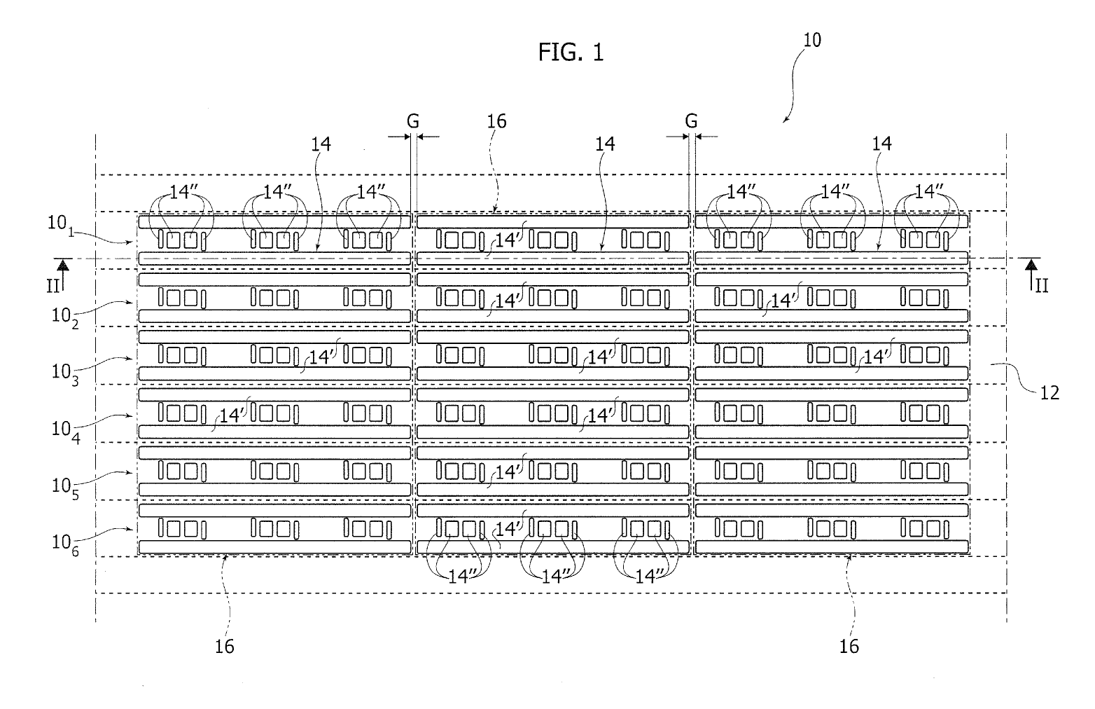

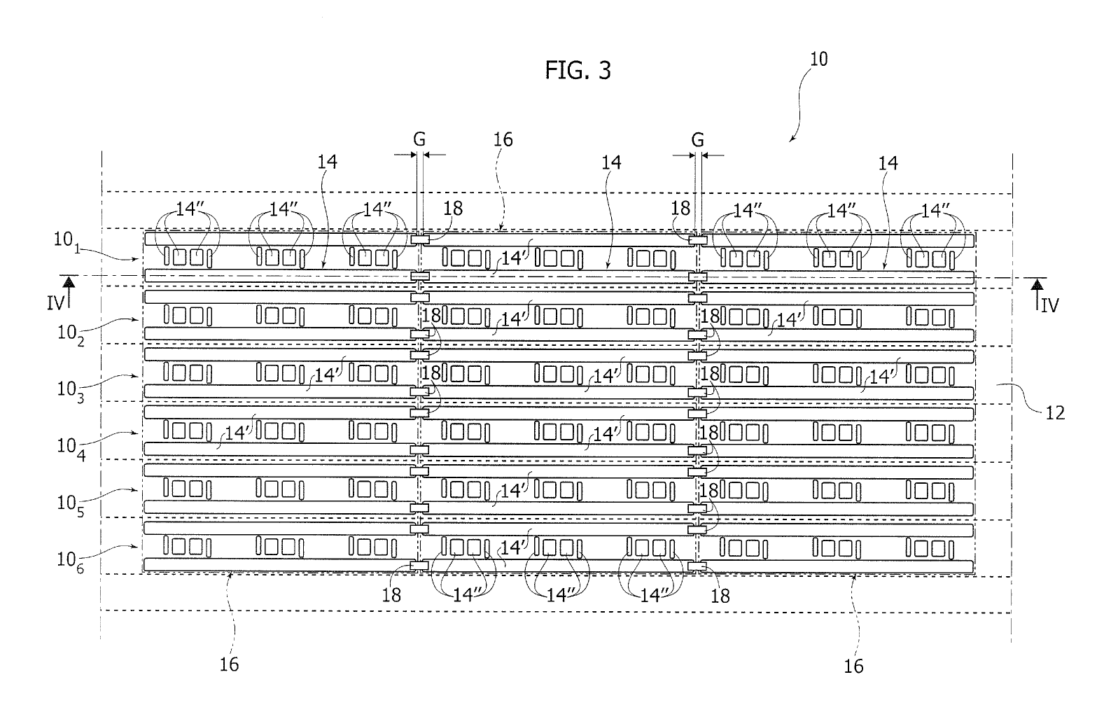

FIGS. 1-5 refer—in general—to the production of lighting devices of the type suitable for use with electrically-powered light radiation sources (for example, solid state light radiation sources, such as LED sources) arranged on a ribbon-like support structure 10, optionally flexible.

For present purposes, such a structure 10 may be considered to have an indefinite length, of which a particular portion or segment is represented in the figures.

One or more embodiments may benefit from the possibility of subdividing the structure 10 by segmenting it or cutting it to length according to the requirements of application and use.

In one or more embodiments, the structure 10 may comprise a ribbon-like substrate 12, for example, of an electrically-insulating material, substantially similar to a substrate for Printed Circuit Boards (PCB) of a flexible type (Flexible PCB or FPCB).

In one or more embodiments, the substrate 12 may comprise materials such as polyimide—PI, polyethylene naphthalate, PEN, polyethyleneimine—PEI, ultra-thin glass.

One or more embodiments, as exemplified in FIG. 1, envisage carrying out a screen printing operation on the substrate 12, which forms a pattern of electrically-conductive lines 14 on a surface of the substrate 12.

In one or more embodiments, the screen printing may use electrically-conductive ink (for example, polymeric ink for thick film printing—Polymer Thick Film—PTF) containing a dispersion of electrically-conductive material such as, for example, (nano)particles of silver and/or copper.

The screen printing forms a series of successive printed images 16, represented in FIGS. 1, 3 and 5 by respective rectangles with dashed lines, which follow one another in the longitudinal direction of the substrate 12. The printed images 16 may comprise respective electrically-conductive lines 14 arranged according to a predetermined pattern. The successive printed images 16 may follow one another along the longitudinal axis of the substrate 12 with the same repeated pattern.

In one or more embodiments, the electrically-conductive lines 14 may comprise longitudinal lines 14′, which may extend continuously over the length of the structure 10 (for example, with a bus function) and connection areas 14″ intended to provide an electric conduction function locally in relation to the light radiation sources.

Again, FIGS. 1-5 refer, purely by way of example, therefore without limiting the scope of the embodiments—to a process aimed at producing, within the ribbon-like structure 10, a certain number of ribbon-like modules 10₁, 10₂, . . . 10₆ (the reference to a number of modules equal to six is merely an example, as these modules may be any number, ideally from 1 to N) initially formed as a single structure and then intended to be separated—operating in a known way—so as to give rise to individual ribbon-like modules usable for producing respective LED modules.

The following part of the present description will, therefore, refer to the structure 10 as a whole, being understood that the operations exemplified with reference to the structure 10 may be carried out with reference to each and every one of the modules 10₁, 10₂, . . . , 10₆ included therein.

In one or more embodiments, the printed images 16 are spaced apart from each other in the longitudinal direction of the substrate 12 by the separation gaps G. The separation gaps G form an offset distance in the order of a few millimeters between consecutive printing images. The separation gaps G may make it easier to avoid possible problems related to tolerance factors and possible smearing of the electrically-conductive ink during the screen printing process.

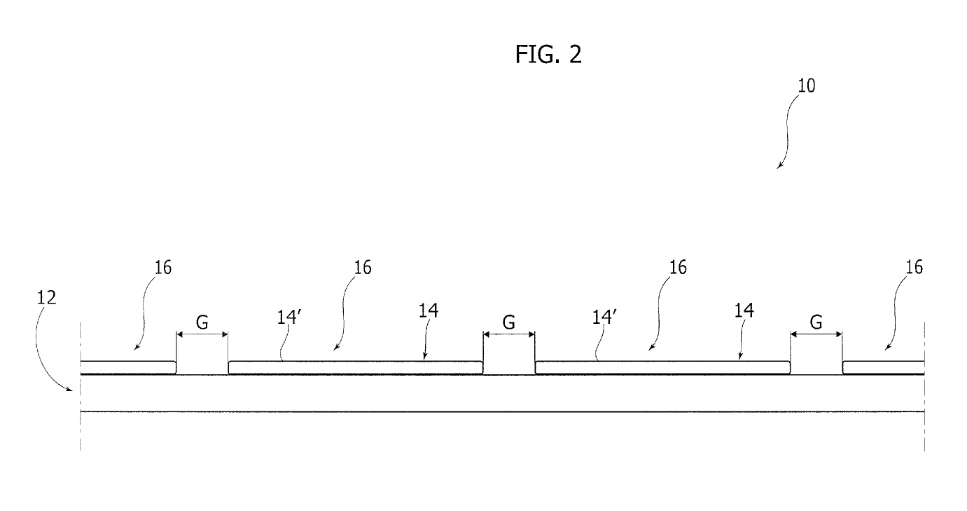

As shown in FIG. 2, at the end of the screen printing, the electrically-conductive lines 14 of the successive printed images 16 are spaced apart from each other by separation gaps G and are devoid of mutual electrical connections. In one or more embodiments the separation gaps G may be provided between mutually facing ends of bus lines 14′ of adjacent printed images 16.

In one or more embodiments, it is possible to provide an electrical continuity between the electrically conductive lines 14 of successive printed images 16. In one or more embodiments, the electrical continuity between the electrically conductive lines 14 of successive printed images 16 may be achieved by forming ink jumpers 18 that extend through the separation gaps G.

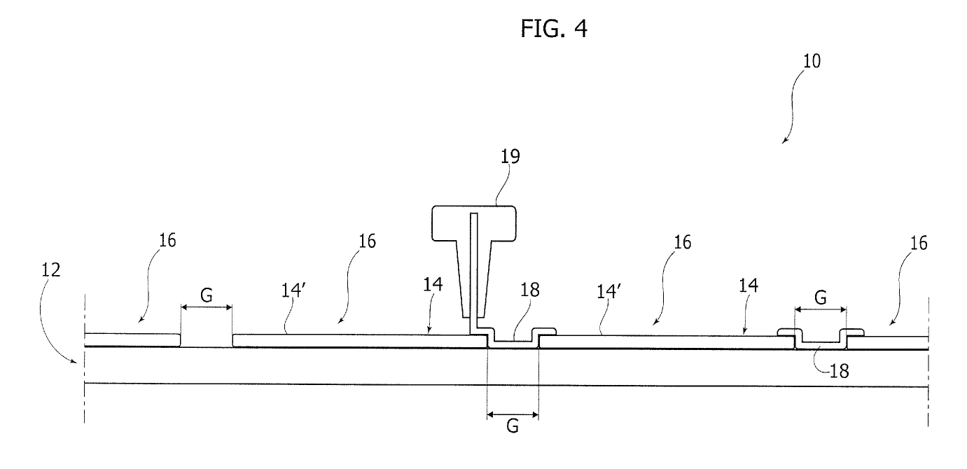

As exemplified in FIG. 4, in one or more embodiments the ink jumpers 18 may be formed by delivering electrically-conductive ink by inkjet printing.

In one or more embodiments, the ink jumpers 18 may connect facing ends of respective bus lines 14′ of adjacent printed images 16 to each other. The interconnection between the bus lines 14′ of two consecutive printed images 16 may be very short, for example, a few millimeters, which results in a short printing time.

In one or more embodiments, the electrically-conductive ink forming the ink jumpers 18 may be dispensed at an inkjet printing station including one or more nozzles 19, located downstream of a screen printing station.

In one or more embodiments, the nozzle 19 is not in contact with the ink applied by means of screen printing, so as to avoid smearing.

In one or more embodiments, the nozzle 10 of the inkjet printing station may deliver the ink forming the ink jumpers 18 onto a three-dimensional surface, for example, on the upper surfaces of the bus lines 14′ and on the uncovered support 12, in a single process step.

In one or more embodiments, the inkjet printing that forms the ink jumpers 18 may be carried out prior to the curing of the ink applied by screen printing.

In one or more embodiments, the curing of the ink may be carried out after the screen printing and the formation of the ink jumpers, for example, in an oven unit located downstream of the screen printing station and the inkjet printing station.

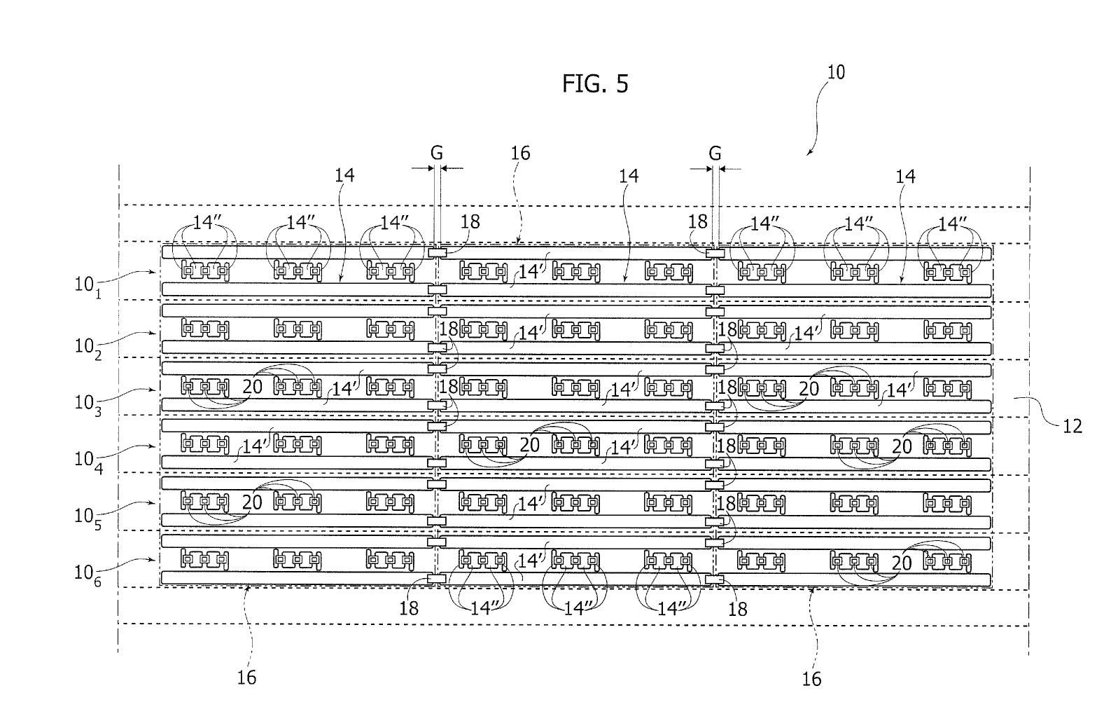

As exemplified in FIG. 5, the manufacturing method of the structure 10 may comprise applying electrically-powered light radiation sources 20, e.g. LED sources to the electrically-conductive lines 14 after curing the electrically-conductive ink. In one or more embodiments, the electrically-powered light radiation sources 20 may be mounted on the support structure 10 using known assembly techniques (for example, SMT techniques).

In one or more embodiments, the operations that lead to producing the support structure 10 may be carried out in a reel-to-reel process, which may envisage the continuous unwinding of the substrate 12 from a first reel, and continuously collecting the finished support structure 10 in a second reel at the end of the process.

One or more embodiments may, therefore, provide a method for forming support structures (e.g. 10) for electrically-powered lighting devices, comprising: providing an electrically insulating ribbon-like substrate (e.g. 12), forming electrically-conductive lines (e.g. 14) on a surface of the substrate (e.g. 12) by screen printing of electrically-conductive ink, the screen printing comprising printing a plurality of repeated printed images (e.g. 16), which follow one another along a longitudinal direction and are separated from each other by separation gaps (e.g. G), and forming electrically-conductive ink jumpers (e.g. 18) that extend through the separation gaps (e.g. G) and which provide electrical continuity between electrically-conductive lines (e.g. 14) of adjacent printed images (e.g. 16), wherein forming ink jumpers (e.g. 18) comprises delivering electrically-conductive ink by inkjet printing.

In one or more embodiments, the method may envisage curing the electrically-conductive ink after screen printing and forming the ink jumpers (e.g. 18).

In one or more embodiments, the ink jumpers (e.g. 18) may connect facing ends of respective bus lines 14′ of adjacent printed images (e.g. 16) to each other.

In one or more embodiments, delivering electrically-conductive ink by inkjet printing may comprise injecting electrically-conductive ink by means of at least one nozzle (e.g. 19) not in contact with the electrically-conductive ink applied by means of screen printing.

In one or more embodiments, the method may comprise applying electrically-powered light radiation sources (e.g. 20) to the electrically-conductive lines (e.g. 14) after curing the electrically-conductive ink.

In one or more embodiments, the method may comprise providing the ribbon-like substrate (e.g. 12) as a reel, and screen printing the electrically-conductive ink onto the ribbon-like substrate (e.g. 12) in a reel-to-reel process.

In one or more embodiments, the method may comprise dividing the support structure (e.g. 10) into a plurality of ribbon-like modules (e.g. 10₁, . . . , 10₆) co-extending along the direction of the length of the support structure (e.g. 10).

In one or more embodiments, a lighting device may comprise: a support structure (for example, 10) produced according to one or more embodiments, and electrically-powered light radiation sources (e.g. 20) arranged on the support structure (e.g. 10) with the light radiation sources (e.g. 20) electrically coupled to the electrically-conductive lines (e.g. 14).

In one or more embodiments: the electrically-powered light radiation sources may comprise LED sources (20), and/or the electrically-powered light radiation sources (e.g. 20) may be mounted onto the support structure (e.g. 10) with SMT technology.

Without prejudice to the underlying principles of the invention, the details of implementation and the embodiments may vary, even significantly, with respect to those illustrated here, purely by way of non-limiting example, without departing from the scope of the invention.

While specific aspects have been described, it should be understood by those skilled in the art that various changes in form and detail may be made therein without departing from the spirit and scope of the aspects of this disclosure as defined by the appended claims. The scope is thus indicated by the appended claims and all changes which come within the meaning and range of equivalency of the claims are therefore intended to be embraced.

### LIST OF REFERENCE SIGNS

support structure 10

ribbon-like substrate 12

electrically-conductive lines 14

printed images 16

longitudinal lines 14′

connection areas 14″

ribbon-like modules 10₁, 10₂, . . . , 10₆

separation gaps

ink jumpers 18

nozzles 19

light radiation sources 20

What is claims is:

1. A method for forming support structures for electrically-powered lighting devices, the method comprising:
providing an electrically insulating ribbon-like substrate,
forming electrically-conductive lines on a surface of the substrate by screen printing of electrically-conductive ink, the screen printing comprising printing a plurality of repeated printed images, which follow one another along a longitudinal direction and are separated from each other by separation gaps, and
forming electrically-conductive ink jumpers that extend through the separation gaps and which provide electrical continuity between electrically-conductive lines of adjacent printed images, wherein forming ink jumpers comprises delivering electrically-conductive ink by inkjet printing.

2. The method according to claim 1, further comprising curing the electrically-conductive ink after the screen printing and forming the ink jumpers.

3. The method according to claim 1, wherein the ink jumpers connect facing ends of respective bus lines of adjacent printed images to each other.

4. The method according to claim 1, wherein delivering electrically-conductive ink by inkjet printing comprises injecting electrically-conductive ink by means of at least one nozzle not in contact with the electrically-conductive ink applied by screen printing.

5. The method according to claim 3, further comprising applying the electrically-powered light radiation sources to the electrically-conductive lines after curing the electrically-conductive ink.

6. The method according to claim 1, further comprising providing the ribbon-like substrate as a reel, and screen printing the electrically-conductive ink on the ribbon-like substrate in a reel-to-reel process.

7. The method according to claim 1, further comprising subdividing the support structure into a plurality of ribbon-like modules co-extending along the length of the support structure.

8. A lighting device, comprising:
a support structure produced with the method comprising:
providing an electrically insulating ribbon-like substrate, forming electrically-conductive lines on a surface of the substrate by screen printing of electrically-conductive ink, the screen printing comprising printing a plurality of repeated printed images, which follow one another along a longitudinal direction and are separated from each other by separation gaps, and
forming electrically-conductive ink jumpers that extend through the separation gaps and which provide electrical continuity between electrically-conductive lines of adjacent printed images, wherein forming ink jumpers comprises delivering electrically-conductive ink by inkjet printing; and
electrically-powered light radiation sources arranged on the support structure with the light radiation sources electrically coupled to the electrically-conductive lines.

9. The lighting device according to claim 8, wherein:
the electrically-powered light radiation sources comprise LED sources, and/or
the electrically-powered light radiation sources are mounted onto the support structure with SMT technology.
